(19) United States
(12) Patent Application Publication
(10) Pub. No.: US 2010/0145548 A1
(43) Pub. Date: Jun. 10, 2010

(54) FAN DRIVING CIRCUIT

(75) Inventors: Guang-Feng Ou, Shenzhen City (CN); You-Xi Ji, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/346,788

(22) Filed: Dec. 30, 2008

(30) Foreign Application Priority Data
Dec. 4, 2008 (CN) 200810305956.7

(51) Int. Cl. G05D 23/00; H02P 1/04; H05K 7/20

(52) U.S. Cl. 700/300; 318/471; 361/695

(57) ABSTRACT

A fan driving circuit includes a temperature sensor, a super input and output (SIO) chip, an integrator, a feedback circuit, and a control circuit. The temperature sensor is configured for measuring a temperature of a computer component and outputting a temperature signal according to the measured temperature. The SIO chip is configured for converting the temperature signal into a digital pulse width modulation (PWM) signal. The integrator is configured for converting the PWM signal into an analog signal. The feedback circuit is configured for processing a driving voltage powering a fan to dissipate heat from the computer component and outputting a feedback signal for to compare with the analog signal. The control circuit is configured for comparing the feedback signal with the analog signal and outputting a new driving voltage to control the speed of the fan.

### BACKGROUND

1. Technical Field

The present disclosure relates to fan driving circuits, and particularly to a fan driving circuit for controlling a speed of a fan.

2. Description of Related Art

Operation of electronic devices or components, such as central processing units (CPUs) may produce large amounts of heat. Generally, fans are used to remove the heat to keep the electronic devices working normally. A driving circuit to control the fan is required.

One such fan driving circuit is connected between a control chip and the fan. The driving circuit is configured for converting a digital pulse width modulation (PWM) signal sent out by the control chip into an analog signal to drive the fan. However, the driving circuit may drive the fan to run at a substantially constant speed whether the electronic device is at a high temperature or at a low temperature.

What is needed, therefore, is to provide a fan driving circuit to overcome the above described shortcoming.

### BRIEF DESCRIPTION OF THE DRAWINGS

FIG. 1 is a block diagram of an exemplary embodiment of a fan driving circuit, together with a computer component and a fan.

FIG. 2 is a circuit diagram of one embodiment of FIG. 1.

### DETAILED DESCRIPTION

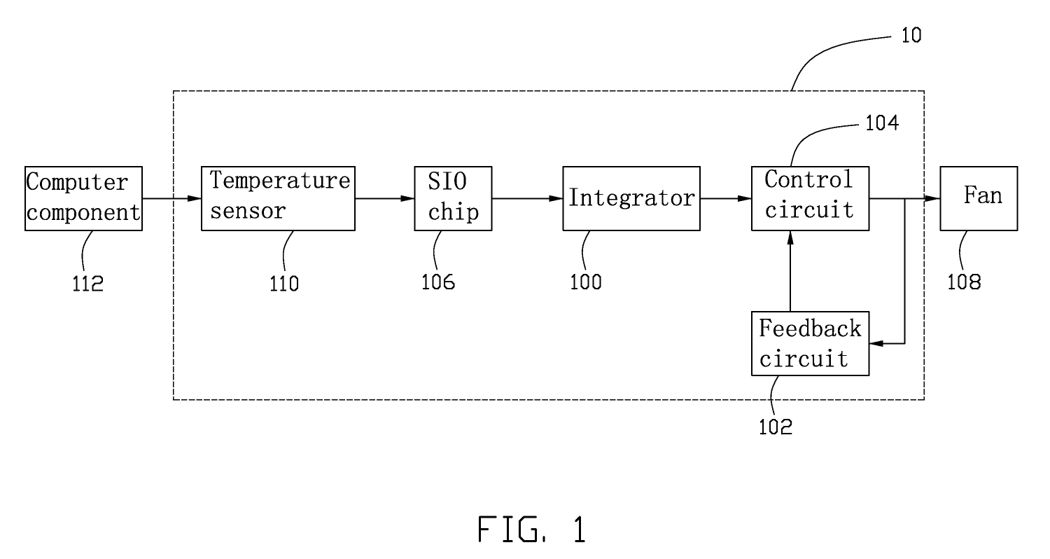

Referring to FIG. 1, an exemplary embodiment of a fan driving circuit 10 is configured for controlling a speed of a fan 108 to efficiently dissipate heat from a computer component 112 and includes a temperature sensor 110, an integrator 100, a feedback circuit 102, a super input and output (SIO) chip 106, and a control circuit 104. The integrator 100 is connected to the SIO chip 106 and the control circuit 104. The SIO chip 106 is also connected to the computer component 112 via the temperature sensor 110. The control circuit 104 is also connected to the feedback circuit 102 and the fan 108. The feedback circuit 102 is also connected to the fan 108. In one embodiment, the computer component 112 is a central processing unit (CPU). In other embodiments, the computer component 112 can be a north bridge chip, a south bridge chip, or a graphics chip.

The temperature sensor 110 is configured for measuring a temperature of the computer component 112 and outputting a temperature signal according to the measured temperature to the SIO chip 106. The SIO chip 106 is configured for converting the temperature signal into a digital pulse width modulation (PWM) signal output to the integrator 100. The integrator 100 is configured for converting the PWM signal into an analog signal output to the control circuit 104 based on a duty cycle of the PWM signal. If the duty cycle is low, the analog signal is at a high level. For example, if the duty cycle of the PWM signal is 10%, the analog signal may be 1.5V. In another example, if the duty cycle of the PWM signal is 80%, the analog signal may be 9V. The feedback circuit 102 is configured for processing a driving signal output from the control circuit 104 to power the fan 108. In this embodiment, the driving signal is a voltage signal and the feedback circuit 102 is configured for sampling and dividing the driving signal and outputting a feedback signal to the control circuit 104. The control circuit 104 is configured for amplifying a voltage difference between the analog signal and the feedback signal and outputting a new driving signal to control the speed of the fan 108.

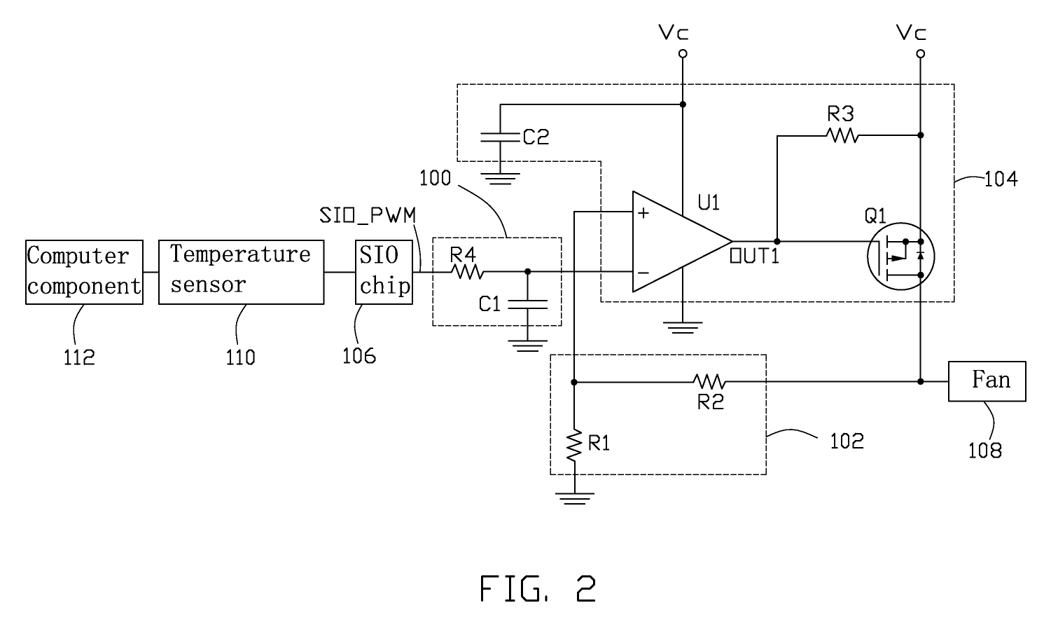

Referring to FIG. 2, the SIO chip 106 includes a PWM signal output pin SIO_PWM. The integrator 100 includes a resistor R4 and a capacitor C1. A first terminal of the resistor R4 is connected to the PWM signal output pin SIO_PWM of the SIO chip 106 to receive the PWM signal. A second terminal of the resistor R4 is grounded via the capacitor C1, and is also connected to the control circuit 104.

The feedback circuit 102 includes two resistors R1 and R2. A first terminal of the resistor R1 is connected to the control circuit 104, and is also connected to the fan 108 via the resistor R2. A second terminal of the resistor R1 is grounded.

The control circuit 104 includes an amplifier U1, a field effect transistor (FET) Q1, a resistor R3, and a capacitor C2. A non-inverting input terminal of the amplifier U1 is connected to a node between the resistors R1 and R2, and an inverting input terminal of the amplifier U1 is connected to a node between the capacitor C1 and the resistor R4. A power terminal of the amplifier U1 is connected to a power supply Vc, and is also grounded via the capacitor C2. A ground terminal of the amplifier U1 is grounded. An output terminal OUT1 of the amplifier U1 is connected to the power supply Vc via the resistor R3, and is also connected to a gate of the FET Q1. A source of the FET Q1 is connected to the power supply Vc. A drain of the FET Q1 is connected to the fan 108.

In the illustrated embodiment, the FET Q1 may be a p-channel metal oxide semiconductor (PMOS) FET. In other embodiments, the FET Q1 may be replaced by other electrical switches, such as a PNP transistor. The power supply Vc is about a 12V power supply in one embodiment. The capacitor C1 is about a 0.1-uF capacitor and the capacitor C2 is about a 10-uF capacitor in one embodiment. A resistance of the resistor R1 is about 3900 ohms in one embodiment. Resistances of the resistors R2, R3 and R4 are all about 10000 ohms in one embodiment.

The following example depicts how the fan driving circuit 10 adjustably controls the speed of the fan 108 according to the temperature of the computer component 112.

When the temperature of the CPU 112 is relatively low, such as 25 degrees Celsius, the SIO chip 106 receives a temperature signal from the temperature sensor 110 at a low level, such as 1.5V, and converts the temperature signal into a PWM signal with a low duty cycle, such as 10%. The integrator 100 converts the PWM signal into an analog signal, such as 1.5V, then outputs to the signal to the inverting input terminal of the amplifier U1. The feedback circuit 102 divides a driving signal currently powering the fan 108 into a feedback signal output to the non-inverting input terminal of the amplifier U1. The amplifier U1 amplifies the voltage difference between the feedback signal and the analog signal and outputs a start voltage at a high level, such as 11V, from the output terminal OUT1 of the amplifier U1. The FET Q1 is turned on, with a small voltage difference between the gate and the source of the FET Q1. A new driving voltage at a low level, such as 6V, is output from the source of the FET Q1 to power the fan 108. The fan 108 runs at a low speed to dissipate heat from the computer component 112.

When the temperature of the CPU 112 is higher, such as 70 degrees Celsius, the SIO chip 106 receives a temperature signal from the temperature sensor 110 at a high level, such as 5V, and converts the temperature signal into a PWM signal with a high duty cycle, such as 80%. The integrator 100 converts the PWM signal into an analog signal, such as 10V, then outputs the signal to the inverting input terminal of the amplifier U1. The feedback circuit 102 divides a driving signal currently powering the fan 108 into a feedback signal output to the non-inverting input terminal of the amplifier U1. The amplifier U1 amplifies the voltage difference between the feedback signal and the analog signal and outputs a start voltage at a lower level, such as 10V, from the output terminal OUT1 of the amplifier U1. The FET Q1 is turned on, with a large voltage difference between the gate and the source of the FET Q1. Thus, the control circuit 104 provides a new driving voltage at a high level, such as 11.5V, to the fan 108. The fan 108 runs at a higher speed to dissipate heat from the computer component 112.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A fan driving circuit for controlling a speed of a fan of a computer component comprising:
a temperature sensor configured for measuring a temperature of the computer component and outputting a temperature signal according to the measured temperature;
a super input and output (SIO) chip configured for converting the temperature signal into a digital pulse width modulation (PWM) signal;
an integrator configured for converting the PWM signal into an analog signal;
a feedback circuit configured for processing a driving signal powering the fan to dissipate heat from the computer component and outputting a feedback signal to compare with the analog signal; and
a control circuit configured for providing the driving signal to the fan and comparing the feedback signal with the analog signal and outputting a new driving signal to control the speed of the fan according to the feedback signal.

2. The fan driving circuit of claim 1, wherein the integrator comprises a resistor and a capacitor; the resistor comprises a first terminal connected to the SIO chip to receive the PWM signal, and a second terminal grounded via the capacitor and also connected to the control circuit.

3. The fan driving circuit of claim 1, wherein the driving signal is a voltage signal, the feedback circuit is configured for sampling and dividing the driving signal and outputting the feedback signal to the control circuit.

4. The fan driving circuit of claim 3, wherein the feedback circuit comprises first and second resistors, a first terminal of the first resistor is connected to the control circuit and is also connected to the fan via the second resistor, a second terminal of the first resistor is grounded.

5. The fan driving circuit of claim 1, wherein the control circuit is connected to the integrator, the feedback circuit and the fan, the control circuit comprises an amplifier and a switch, a non-inverting input terminal of the amplifier is connected to the feedback circuit, an inverting input terminal of the amplifier is connected to the integrator, a power terminal of the amplifier is connected to a power supply, a ground terminal of the amplifier is grounded, an output terminal of the amplifier is connected to the power supply via a resistor and is also connected to a first terminal of the switch, a second terminal of the switch is connected to the power supply, a third terminal of the switch is connected to the fan; the control circuit configured for controlling the switch to be turned on to provide the new driving signal to the fan if the temperature of the computer component is changed.

6. The fan driving circuit of claim 1, wherein the control circuit further comprises a capacitor connected between a power supply and ground.

7. The fan driving circuit of claim 4, wherein the switch is a p-channel metal oxide semiconductor field effect transistor (PMOS FET), the first, second, and third terminal of the switch correspond to a gate, a source, and a drain of the PMOS FET.

8. The fan driving circuit of claim 5, wherein the switch is a PNP transistor.

9. The fan driving circuit of claim 5, wherein the power supply is a 12V power supply.

10. The fan driving circuit of claim 1, wherein the computer component is a central processing unit.

11. The fan driving circuit of claim 1, wherein the computer component is a graphics chip.

12. The fan driving circuit of claim 1, wherein the computer component is a north bridge chip.
